(19) United States
(12) Patent Application Publication
(10) Pub. No.: US 2022/0320408 A1
(43) Pub. Date: Oct. 6, 2022

(54) ENCLOSURES FOR THERMOELECTRIC GENERATORS, AND RELATED DEVICES, SYSTEMS, AND METHODS

(71) Applicant: Baker Hughes Oilfield Operations LLC, Houston, TX (US)

(72) Inventors: Navin Sakthivel, Spring, TX (US); Aaron Avagliano, Tomball, TX (US); Chad Yates, Houston, TX (US)

(21) Appl. No.: 17/326,136

(22) Filed: May 20, 2021

Related U.S. Application Data
(60) Provisional application No. 63/169,723, filed on Apr. 1, 2021.

(51) Int. Cl. H01L 35/32; H01L 35/16; H01L 35/22; H01L 35/34

(52) U.S. Cl. CPC H01L 35/32; H01L 35/16; H01L 35/22; H01L 35/34

(57) ABSTRACT

An enclosure for a thermoelectric generator may include bonded particles of an allotrope of carbon, such as diamond particles, graphene particles, and/or carbon nanotube particles. A thermoelectric generator system may include one or more thermoelectric generators positioned at least partially within the enclosure. The enclosure may be manufactured using an additive manufacturing process which may include providing particles of an allotrope of carbon, and selectively binding a portion of the particles with a binder material. The bound particles may then be sintered to form the enclosure.

### CROSS-REFERENCE TO RELATED APPLICATION

This application claims the benefit under 35 U.S.C. § 119(e) of U.S. Provisional Patent Application Serial No. 63/169,723, filed Apr. 1, 2021, the disclosure of which is hereby incorporated herein in its entirety by this reference.

### TECHNICAL FIELD

Embodiments of the present disclosure generally relate to methods, systems, and devices for providing enclosures for thermoelectric generators and components thereof. More particularly, embodiments of the present disclosure relate to methods, systems, and devices for providing enclosures for thermoelectric generators and components thereof from allotropes of carbon, such as diamond, graphene, fullerenes, and/or carbon nanotubes, utilizing additive manufacturing.

### BACKGROUND

Thermoelectric generators are devices that convert heat energy into electric energy, such as by the Seebeck effect. For example, a thermoelectric generator may comprise two dissimilar metals, which may produce electricity in response to a thermal gradient (e.g., a difference in temperature between a first side and an opposing second side). The performance of a thermoelectric generator at producing electricity is dependent on the difference in temperature between a first side (a “hot side”) and a second side (a “cold side”). By increasing the temperature of the hot side and/or decreasing the temperature of the cold side, the thermal gradient between the hot side and the cold side may be increased and the production of electricity by the thermoelectric generator may be increased.

### BRIEF SUMMARY

In some embodiments, the present disclosure includes enclosures for a thermoelectric generator that may include bonded particles of an allotrope of carbon, such as diamond particles, graphene particles, and/or carbon nanotube particles.

In additional embodiments, the present disclosure includes thermoelectric generator systems including an enclosure comprised of bonded particles of an allotrope of carbon, and at least one thermoelectric generator positioned at least partially within the enclosure.

Further embodiments of the present disclosure include methods of manufacturing an enclosure for a thermoelectric generator. The methods may include providing particles of an allotrope of carbon, and selectively binding a portion of the particles with a binder material.

### BRIEF DESCRIPTION OF THE DRAWINGS

While the specification concludes with claims particularly pointing out and distinctly claiming embodiments of the present disclosure, the advantages of embodiments of the disclosure may be more readily ascertained from the following description of embodiments of the disclosure when read in conjunction with the accompanying drawings in which:

FIG. 1 is a cross-sectional view of a thermoelectric generator system including an enclosure according to an embodiment of the present disclosure;

FIG. 2 is a cross-sectional view of a thermoelectric generator system including a plurality of thermoelectric generators according to an embodiment of the present disclosure;

FIG. 3 is a cross-sectional view of a thermoelectric generator system including a thermoelectric generator partially enclosed within an enclosure according to an embodiment of the present disclosure; and

FIG. 4 is a cross-sectional view of a thermoelectric generator system including a thermoelectric generator partially enclosed within an enclosure including fin structures according to an embodiment of the present disclosure.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, system, and process changes may be made without departing from the scope of the disclosure.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

Furthermore, specific implementations shown and described are only examples and should not be construed as the only way to implement the present disclosure unless specified otherwise herein. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

As used in this specification, the terms “substantially,” “about,” and “approximately” in reference to a given parameter, property, or condition means and includes to a degree that one skilled in the art would understand that the given parameter, property, or condition is met with a small degree of variance, such as within acceptable manufacturing tolerances. For example, a parameter that is substantially met may be at least about 90% met, at least about 95% met, at least about 99% met, or even 100% met.

The phrase “at least one of” when used with a list of items means different combinations of one or more of the listed items may be used and only one of each item in the list may be needed. For example, “at least one of item A, item B, and item C” may include, without limitation, item A or item A and item B. This example may also include item A, item B, and item C, or item B and item C. In other examples, “at least one of” may be, without limitation, two of item A, one of item B, and 10 of item C; four of item B and seven of item C; and other suitable combinations.

As used in this disclosure, any relational term, such as “first,” “second,” “over,” “top,” “bottom,” “side,” etc., is used for clarity and convenience in understanding the disclosure and accompanying drawings and does not connote or depend on any specific preference, orientation, or order, except where the context clearly indicates otherwise.

As used in this disclosure, the term “and/or” means and includes any and all combinations of one or more of the associated listed items.

The illustrations presented in this disclosure are not meant to be actual views of any particular system or device, but are merely idealized representations that are employed to describe the disclosed embodiments. Thus, the drawings are not necessarily to scale and relative dimensions may have been exaggerated for the sake of clarity. Additionally, elements common between figures may retain the same or similar numerical designation.

The following description provides specific details in order to provide a thorough description of embodiments of this disclosure. However, a person of ordinary skill in the art will understand that the embodiments of this disclosure may be practiced without employing these specific details.

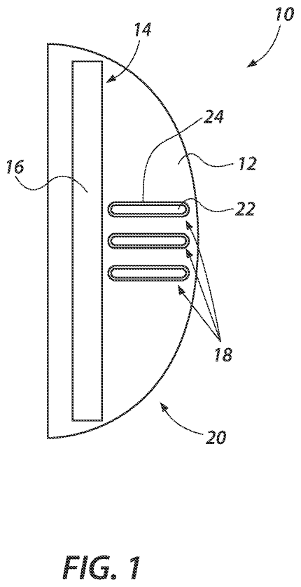

FIG. 1 shows a cross-sectional view of a thermoelectric generator system 10 including an enclosure 12 according to an embodiment of the present disclosure. The enclosure 12 may include a cavity 14 sized to receive a thermoelectric generator 16 therein. Optionally, the enclosure 12 may additionally include a heat transfer device therein, such as one or more integral heat pipes 18.

The enclosure 12 may be comprised of bonded particles of an allotrope of carbon. For example, the enclosure 12 may be comprised of a particle-matrix composite material comprising particles of an allotrope of carbon, such as diamond, bonded together, such as with a matrix material.

In some embodiments, the particles may comprise greater than 30% by volume of the particle-matrix composite material. For example, the particles may comprise between 30% and 85% by volume of the particle-matrix composite material. The particles may be a variety of sizes to optimize packing of the particles in the particle-matrix composite material. For example, the particles may have an average size in a range of between about 0.5 μm and about 100 μm. The particles may have a monomodal particle size distribution, or a multimodal particle size distribution.

In some embodiments, the matrix material may comprise a ceramic material, such as silicon carbide, silica, titanium oxide and/or aluminum oxide, for example. In further embodiments, the matrix material may comprise a semiconductor material, such as silicon (with or without other elements). In yet further embodiments, the matrix material may comprise a metal or metal alloy, which may be based on one or more of copper and/or aluminum, for example.

Such particle-matrix composite materials containing allotropes of carbon, such as diamond, may have relatively high thermal conductivity, such as greater than about 1,600 watts per meter-kelvin (W/mK), compared to copper's thermal conductivity of about 400 W/mK. In some embodiments, the particles of an allotrope of carbon may comprise one or more of diamond, graphene, and carbon nanotubes.

In some embodiments, the thermoelectric generator 16 may comprise two dissimilar conductors, such as two dissimilar metals. In further embodiments, the thermoelectric generator 16 may comprise a semiconductor material. In some embodiments, the thermoelectric generator 16 may comprise one or more of lead telluride, silicon germanium, and manganese oxide. For example, lead telluride may be utilized for temperatures up to about 850° kelvin (K), silicon germanium may be utilized for temperatures up to about 1,300° K, and manganese oxide may be utilized for temperatures up to about 1,300° K

The enclosure 12 may be manufactured using additive manufacturing techniques, which may facilitate the manufacturing of complex shapes with relative ease and may achieve geometries that may otherwise be difficult or impossible to achieve. Accordingly, the enclosure 12 may include non-planar, and non-uniform features. For example, the enclosure 12 may comprise a surface 20 configured to interface and conform to a non-planar and/or non-uniform surface of a heat source.

Some systems and devices that may be located in proximity to a heat source, and that may benefit from receiving electricity from a thermoelectric generator, may include complex geometries in regions that might be considered for the inclusion of the thermoelectric generator. For example, earth-boring tools for drilling such as for energy exploration may be exposed to heat downhole from thermal energy that naturally occurs within the earth's crust. Additional examples of tools and structures that may benefit from receiving electricity from a thermoelectric generator include pipelines, fractional columns, refinery units, and distillation columns. Such tools and structures, however, may include complex geometries, such as curved surfaces, in regions that may be considered for the placement of a thermoelectric generator. Accordingly, the enclosure 12 may include one or more irregular surfaces that may be sized and configured to mate with an irregular surface where the thermoelectric generator system 10 is located.

In some embodiments, an irregular surface may provide a heat source to the thermoelectric generator system 10. Accordingly, heat from the irregular surface may be effectively transmitted into the enclosure 12 at the interface between the irregular surface of the heat source and the corresponding irregular surface 20 of the enclosure 12. The relatively high thermal conductivity of the enclosure 12 may then efficiently deliver heat to the hot side of the thermoelectric generator 16.

In some embodiments, an irregular surface may be relatively cool and provide a heat sink to the thermoelectric generator system 10. Accordingly, heat from the cold side of the thermoelectric generator 16 may be effectively transmitted through the enclosure 12 and into the heat sink at the interface between the irregular surface of the heat sink and the corresponding irregular surface 20 of the enclosure 12.

Each integral heat pipe 18, may include a fluid located therein, which may facilitate the transfer of heat from a hot side to a cold side. Each integral heat pipe 18 may include a combination of open channels 22 and capillary channels 24. Heat may be applied to the fluid located at the hot side, which may cause the fluid located at the hot side to change from a liquid phase to a gas phase. The gas phase fluid may then travel through one or more open channels 22 to the cold side. The gas phase fluid located at the cold side may then be cooled, which may cause the fluid located on the cool side to change from the gas phase back to the liquid phase. The liquid phase fluid may then travel through one or more capillary channels 24 via capillary action (e.g., wicking) back to the hot side. As the fluid within each integral heat pipe 18 moves back and forth between the hot side and the cold side, the fluid may transfer heat from the hot side to the cold side.

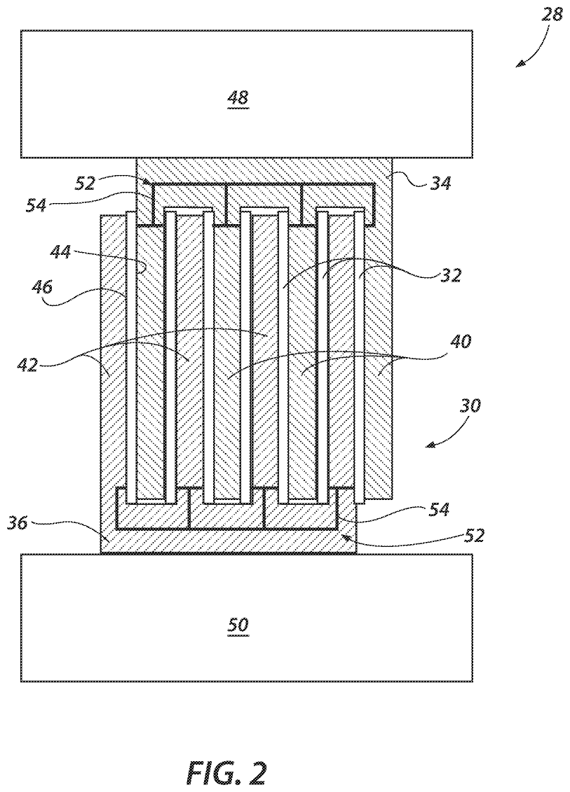

In some embodiments, a thermoelectric generator system 28 may include an enclosure 30 comprised of bonded particles of an allotrope of carbon, the enclosure 30 configured to accommodate a plurality of thermoelectric generators 32, as shown in FIG. 2. The enclosure 30 may comprise a first structure (e.g., a hot side structure 34) and a second structure (e.g., a cold side structure 36). Each of the hot side structure 34 and the cold side structure 36 may be comprised of a particle-matrix composite material comprising particles of an allotrope of carbon, such as diamond, bonded together, such as with a matrix material. The hot side structure 34 may include first fin structures 40 and the cold side structure 36 may comprise second fin structures 42, and the first fin structures 40 and the second fin structures 42 may intermesh. The thermoelectric generators 32 may be positioned between the first fin structures 40 of the hot side structure 34 and the second fin structures 42 of the cold side structure 36.

Each of the thermoelectric generators 32 may comprise a hot side 44 and a cold side 46. The cold side 46 of each thermoelectric generator 32 may be positioned proximate to a second fin structure 42 of the cold side structure 26 of the enclosure 30. The hot side 44 of each thermoelectric generator 32 may be positioned proximate to a first fin structure 40 of the hot side structure 34 of the enclosure 30. Accordingly, the fin structures 40, 42 of the hot side structure 34 and the cold side structure 36 may be separated by the thermoelectric generators 32, and the hot side structure 34 and the cold side structure 36 of the enclosure 30 may not be in contact with one another.

In operation, heat may be applied to the hot side structure 34 of the enclosure 30 by a heat source 48, and heat may be extracted from the cold side structure 36 of the enclosure 30 by a heat sink 50. The heat applied to the hot side structure 34 may travel through the first fin structures 40 to the hot side 44 of each of the thermoelectric generators 32. The heat may then be extracted from the cold side 46 of each of the thermoelectric generators 32 through the second fin structures 42 of the cold side structure 36.

The enclosure 30 may include channels 52 within each of the cold side structure 36 and the hot side structure 34 with electrical circuits 54 contained therein. The electrical circuits 54 may comprise wires routed through the channels 52, and/or electrically conductive material deposited within the channels 52.

The electrical circuits 54 within the cold side structure 36 may be electrically connected to the cold side 46 of each of the thermoelectric generators 32. Likewise, the electrical circuits 54 within the hot side structure 34 may be electrically connected the hot side 44 of each of the thermoelectric generators 32. The electrical circuits 54 may also be coupled to a power storage device (not shown), such as a battery, and/or may be coupled to another electrical device that may be powered by electrical current that is generated by the thermoelectric generators 32.

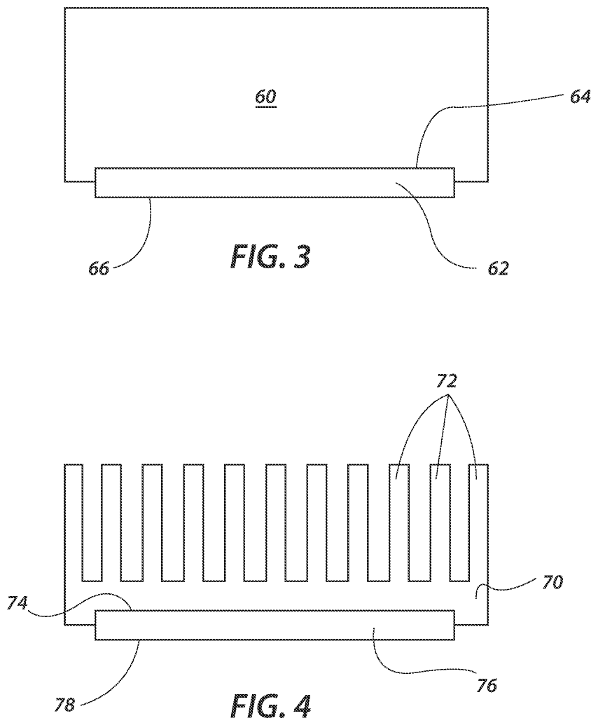

In some embodiments, an enclosure 60 comprised of bonded particles of an allotrope of carbon may be configured to surround only a portion of a thermoelectric generator 62, as shown in FIG. 3. For example, a cold side 64 of the thermoelectric generator 62 may be positioned proximate to, and/or within, the enclosure 60. A hot side 66 of the thermoelectric generator 62 may be exposed, such that the hot side 66 of the thermoelectric generator 62 may be directly exposed to a heat source. The enclosure 60 may act as a heat sink, drawing heat from the cold side 64 of the thermoelectric generator 62, which may increase the temperature gradient across the thermoelectric generator 62 and increase electrical output.

In some embodiments, an enclosure 70 comprised of bonded particles of an allotrope of carbon may be configured with features, such as fin structures 72, as shown in FIG. 4, which may improve heat transfer between the enclosure 70 and a surrounding fluid. In some embodiments, the features, such as the fin structures 72, may increase the surface area of the enclosure 70 that is exposed to the surrounding fluid. For example, a cold side 74 of a thermoelectric generator 76 may be positioned proximate to, and/or within, the enclosure 70, and a hot side 78 of the thermoelectric generator 76 may exposed to a heat source. The enclosure 70 may act as a heat sink, drawing heat from the cold side 74 of the thermoelectric generator 76, and the fin structures 72 may facilitate the transfer of the heat from the enclosure 70 to a surrounding fluid.

Enclosures 12, 30, 60, 70 according to embodiments of the present disclosure may be manufactured using additive manufacturing methods (e.g., 3-D printing). For example, additive manufacturing methods such as described in International Publication Number WO 2017/032842 A1 published under the Patent Cooperation Treaty (PCT) on Mar. 2, 2017, and titled “DIAMOND COMPOSITES BY LITHOGRAPHY-BASED MANUFACTURING” which is incorporated by reference herein in its entirety, may be utilized.

In some embodiments, a slurry may be utilized that includes between about 70% to about 90% by weight particles of an allotrope of carbon, such as diamond, in a liquid temporary binder. The liquid temporary binder may be a monomer and/or a polymer that may cure and harden when exposed to a specific wavelength or spectrum of light. For example, the liquid temporary binder may be a polymer that may cure and harden when exposed to light from one or more lasers.

Portions of the liquid temporary binder may be selectively cured and hardened, such as by directing laser light on selected portions of the liquid temporary binder, in a layer-by-layer process, wherein the combined layers of hardened temporary binder may define the shape of the enclosure 12, 30, 60, 70 in the form of a green body.

The green body may then be subjected to a de-binding step wherein the green body may be subjected to heat and/or a supercritical fluid. As a non-limiting example, supercritical carbon dioxide (CO₂) may be utilized. The de-binding step may remove and/or carbonize the temporary binder to form a white body.

An infiltrant may then be introduced to the white body and the white body may be sintered to consolidate the structure and form the enclosure 12, 30, 60, 70. In some embodiments, the infiltrant may comprise silicon to form a silicon-carbide matrix. In further embodiments, the infiltrant may be selected from silicon, silicon compositions, copper, copper alloys, aluminum, and aluminum alloys. The sintering process may involve exposing the infiltrated white body to elevated temperatures to reduce porosity and consolidate the white body to form the enclosure 12, 30, 60, 70. As a non-limiting example, the sintering process may involve exposing the infiltrated white body to temperatures in the range of about 1500° C. to about 1750° C.

While certain illustrative embodiments have been described in connection with the figures, those of ordinary skill in the art will recognize and appreciate that the scope of this disclosure is not limited to those embodiments explicitly shown and described in this disclosure. Rather, many additions, deletions, and modifications to the embodiments described in this disclosure may be made to produce embodiments within the scope of this disclosure, such as those specifically claimed, including legal equivalents. In addition, features from one disclosed embodiment may be combined with features of another disclosed embodiment while still being within the scope of this disclosure.

1. An enclosure for a thermoelectric generator, the enclosure comprised of bonded particles of an allotrope of carbon, the enclosure comprising a surface configured to interface and conform to a non-planar surface of a heat source, the enclosure configured to at least partially enclose at least one thermoelectric generator.

2. The enclosure of claim 1, wherein the bonded particles are diamond particles.

3. The enclosure of claim 1, wherein the bonded particles are graphene particles.

4. The enclosure of claim 1, wherein the bonded particles are carbon nanotube particles.

5. The enclosure of claim 1, wherein the thermal conductivity of the enclosure is greater than about 1,600 W/mK.

6. The enclosure of claim 1, further comprising an integral heat pipe.

7. (canceled)

8. The enclosure of claim 1, further comprising channels with electrical circuits contained therein.

9. The enclosure of claim 1, further comprising:
a first structure comprising first fin structures defining first channels between the first fin structures; and
a second structure comprising second fin structures defining second channels between the second fin structures, the first fin structures and the second fin structures sized and configured to intermesh with thermoelectric generators positioned in remaining spaces of the first channels and the second channels between the first fin structures and the second fin structures.

10. A thermoelectric generator system, the system comprising:
an enclosure comprised of bonded particles of an allotrope of carbon, the enclosure comprising at least one cavity sized to receive at least one thermoelectric generator therein; and
a thermoelectric generator of the at least one thermoelectric generator positioned at least partially within a respective cavity of the at least one cavity of the enclosure such that a first side of the thermoelectric generator is within the cavity, and a second, opposite side of the thermoelectric generator is external to the cavity.

11. The thermoelectric generator system of claim 10, wherein the at least one thermoelectric generator comprises one or more of lead telluride, silicon germanium, and manganese oxide.

12. The thermoelectric generator system of claim 10, wherein the at least one thermoelectric generator comprises a plurality of thermoelectric generators.

13. The thermoelectric generator system of claim 10, wherein the bonded particles are diamond particles.

14. The thermoelectric generator system of claim 10, wherein the bonded particles are graphene particles.

15. The thermoelectric generator system of claim 10, wherein the bonded particles are carbon nanotube particles.

16. The thermoelectric generator system of claim 10, wherein the enclosure comprises:
a first structure comprising first fin structures; and
a second structure comprising second fin structures, the first fin structures and the second fin structures intermeshed and a plurality of thermoelectric generators positioned between the first fin structures and the second fin structures.

17. The thermoelectric generator system of claim 16, wherein a hot side of each thermoelectric generator of the plurality of thermoelectric generators is in contact with the first structure, and a cold side of each thermoelectric generator of the plurality of thermoelectric generators is in contact with the second structure.

18-21. (canceled)

22. The enclosure of claim 1, wherein the surface of the enclosure is connected to an oil and gas apparatus selected from an earth-boring tool, a pipeline, a fractional column, a refinery unit, and a distillation column.

23. The enclosure of claim 1, wherein the enclosure is additively manufactured.
